(19) United States
(12) Patent Application Publication
(10) Pub. No.: US 2026/0299073 A1
(43) Pub. Date: Oct. 1, 2026

(54) POWER SUPPLY SYSTEM AND MOVING OBJECT

(71) Applicant: HONDA MOTOR CO., LTD., Tokyo (JP)

(72) Inventor: Manabu Mitani, Wako-shi (JP)

(21) Appl. No.: 19/574,641

(22) Filed: Mar. 23, 2026

(30) Foreign Application Priority Data
Mar. 25, 2025 (JP) 2025-049767

(51) Int. Cl. G01R 35/04; B64C 29/00; B64D 27/35; B64D 31/16; B64D 45/00; G01R 31/3832; G01R 31/396; H02J 1/08

(52) U.S. Cl. CPC G01R 35/04; B64C 29/0016; B64D 27/35; B64D 31/16; B64D 45/00; G01R 31/3832; G01R 31/396; H02J 1/08; B64D 2045/0085; B64D 2221/00

(57) ABSTRACT

A management control device determines whether or not a first electrical current sensor has malfunctioned, based on a comparison between an electrical current flowing into a first electrical power storage control device and detected by the first electrical current sensor, an electrical current flowing into the first electrical power storage control device and detected by a second electrical current sensor, an electrical current flowing from an electrical power generating device to a first electrical power transmission bus and detected by a third electrical current sensor, and an electrical current flowing from the first electrical power transmission bus to a first load device and detected by a fourth electrical current sensor.

### CROSS-REFERENCE TO RELATED APPLICATIONS

This application is based upon and claims the benefit of priority from Japanese Patent Application No. 2025-049767 filed on Mar. 25, 2025, the contents of which are incorporated herein by reference.

### BACKGROUND OF THE INVENTION

### Field of the Invention

The present disclosure relates to an electrical power supply system and a moving object.

### Description of the Related Art

In JP 2023-148637 A, an electrical power supply system is disclosed. The electrical power supply system includes a power supply controller. The power supply controller, in a malfunction determination unit, and based on an electrical current detected by each of respective electrical current sensors, determines whether or not each of the respective electrical current sensors of an electrical power supply circuit has malfunctioned.

### SUMMARY OF THE INVENTION

There is a long awaited need for a more satisfactory electrical power supply system and the like.

The present invention has the object of solving the aforementioned problem.

A first aspect of the present disclosure is characterized by an electrical power supply system comprising a first electrical power transmission bus configured to supply, to a first load device, a direct current electrical power output from an electrical power generating device and a direct current electrical power output from a first electrical power storage device configured to be disposed in parallel with the electrical power generating device, a first electrical current sensor and a second electrical current sensor each configured to detect an electrical current flowing through a first connection circuit configured to connect the first electrical power storage device and the first electrical power transmission bus, a third electrical current sensor configured to detect an electrical current flowing through the first electrical power transmission bus, at a location closer to the electrical power generating device than is a connected location between the first electrical power transmission bus and the first connection circuit, a fourth electrical current sensor configured to detect an electrical current flowing through the first electrical power transmission bus, at a location closer to the first load device than is the connected location between the first electrical power transmission bus and the first connection circuit, a first electrical power storage control device including a first information acquisition unit configured to acquire first electrical current information indicating the electrical current detected by the first electrical current sensor, and acquire second electrical current information indicating the electrical current detected by the second electrical current sensor, and a management control device configured to manage the first electrical power storage control device, wherein the management control device includes a second information acquisition unit configured to acquire the first electrical current information and the second electrical current information from the first electrical power storage control device, and acquire third electrical current information indicating the electrical current detected by the third electrical current sensor, and fourth electrical current information indicating the electrical current detected by the fourth electrical current sensor, and a sensor malfunction determination unit configured to determine whether or not the first electrical current sensor has malfunctioned based on a comparison between the first electrical current information, the second electrical current information, the third electrical current information, and the fourth electrical current information.

A second aspect of the present disclosure is characterized by a moving object equipped with the electrical power supply system according to the first aspect.

According to the present disclosure, it is possible to provide a more satisfactory electrical power supply system and the like.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a schematic diagram of a moving object according to one embodiment;

FIG. 2 is a schematic diagram showing a configuration of an electrical power supply system according to the one embodiment;

FIG. 3 is a block diagram showing a configuration of a first electrical power storage control device according to the one embodiment;

FIG. 4 is a block diagram showing a configuration of a second electrical power storage control device according to the one embodiment;

FIG. 5 is a block diagram showing a configuration of a management control device according to the one embodiment;

FIG. 6 is a flowchart of an SOC management control according to the one embodiment; and

FIG. 7 is a flowchart of the SOC management control according to the one embodiment.

### DETAILED DESCRIPTION OF THE INVENTION

A moving object, which is an electric vertical take-off and landing aircraft (eVTOL aircraft), is equipped with an electrical power supply system that includes two types of electrical power sources, namely, an electrical power generating device having a generator that is driven by an engine, and an electrical power storage device having a battery.

In order to prevent the electrical power storage device from being excessively charged or excessively discharged, it is necessary to manage an SOC (State Of Charge) of the electrical power storage device. The SOC of the electrical power storage device changes depending on the charge that is input to and output from the electrical power storage device. Therefore, the SOC of the electrical power storage device can be determined by integrating over time the electrical current that flows into the electrical power storage device.

The electrical current flowing into the electrical power storage device that is detected by the electrical current sensor is transmitted as electrical current information to an electrical power storage control device that monitors the electrical power storage device. The electrical power storage control device determines the SOC of the electrical power storage device based on the electrical current information, and transmits SOC information indicating the SOC of the electrical power storage device to a management control device, which is a higher level control device.

In order to provide redundancy for the electrical current sensors that detect the electrical current flowing into the electrical power storage device, and together therewith, in order to identify a malfunctioning electrical current sensor, it may be considered to provide three electrical current sensors.

However, by increasing the number of the electrical current sensors, problems occur such as an increase in weight, size, and high cost of the electrical power supply system.

The electrical power supply system of the present disclosure is capable of suppressing an increase in weight, size, and high cost.

### EMBODIMENTS

### [Configuration of Moving Object]

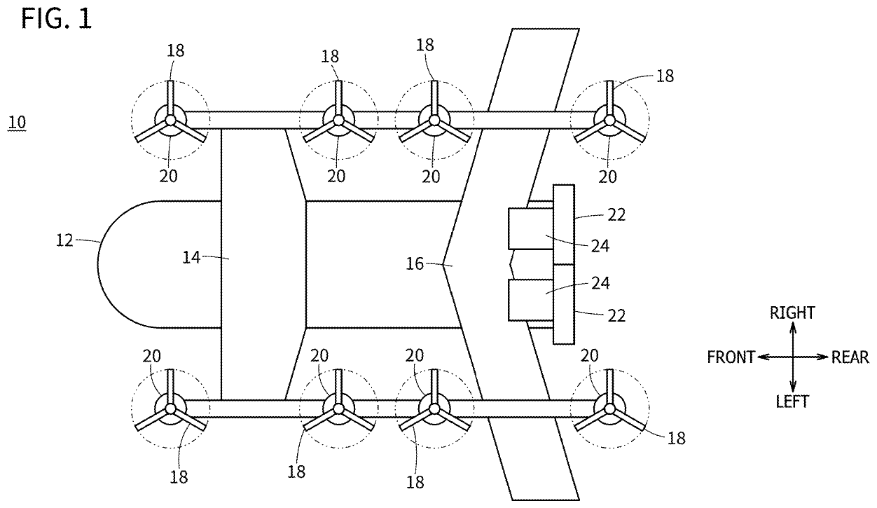

FIG. 1 is a schematic diagram of a moving object 10 according to one embodiment. The moving object 10 of the one embodiment is an electric vertical take-off and landing aircraft (eVTOL aircraft). The moving object 10 includes a fuselage 12. A cockpit, a cabin, and the like are provided in the fuselage 12. A pilot sits in the cockpit, and controls the moving object 10. Passengers and others board and ride in the cabin. The moving object 10 may be automatically controlled.

The moving object 10 includes a front wing 14 and a rear wing 16. In the case that the moving object 10 moves frontward, a lift is generated respectively on each of the front wing 14 and the rear wing 16.

The moving object 10 is equipped with eight VTOL rotors 18, and two cruise rotors 22. One VTOL electric motor 20 is provided for one of the VTOL rotors 18. The VTOL electric motor 20 is a single three phase motor. One cruise electric motor 24 is provided for one of the cruise rotors 22. The cruise electric motor 24 is a dual three phase motor.

### [Configuration of Electrical Power Supply System]

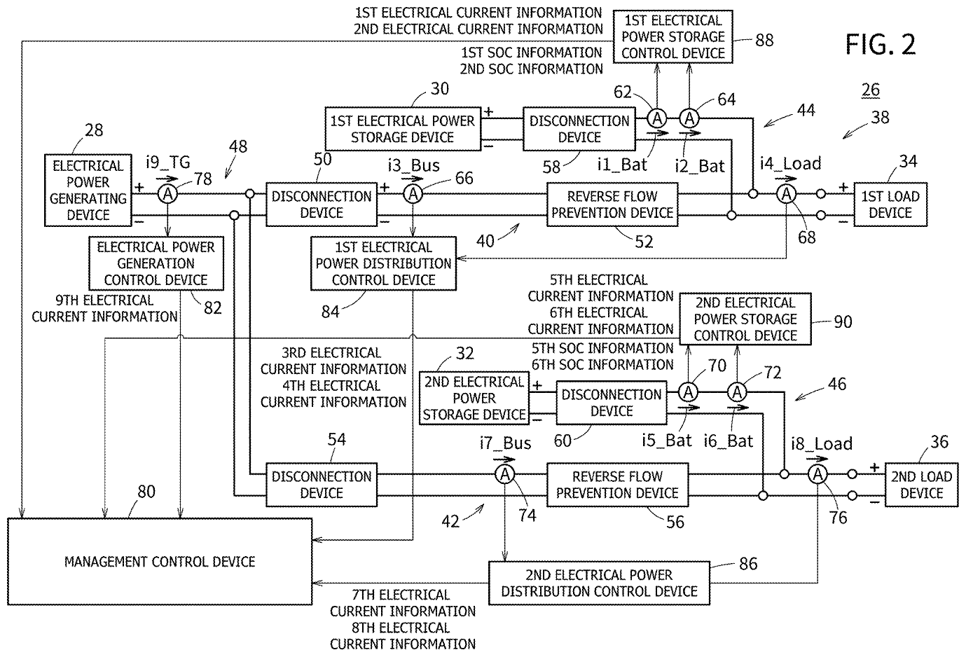

FIG. 2 is a schematic diagram of an electrical power supply system 26 according to the one embodiment. The electrical power supply system 26 is mounted in the moving object 10.

The electrical power supply system 26 is equipped with an electrical power generating device 28 that serves as a main electrical power source. The electrical power generating device 28 includes an engine, a generator, and a power drive unit (hereinafter referred to as a PDU), none of which are shown. The engine, for example, is a gas turbine engine. The engine, instead of being a gas turbine engine, may be a reciprocating engine. The generator, for example, is a motor generator. By the engine driving the generator, the generator carries out generation of electrical power. The PDU is a converter having switching elements. By controlling the switching elements, the PDU converts an AC electrical power generated by the generator into a DC electrical power and outputs the DC electrical power.

In the case that the engine is started, by controlling the switching elements, the PDU converts the DC electrical power that was input to the PDU into a three phase AC electrical power, and outputs the AC electrical power to the generator. In this case, the PDU functions as an inverter. The three phase AC electrical power runs the generator, and the generator causes the engine to start.

The electrical power generating device 28 may include various sensors such as voltage sensors or the like, and various elements such as fuses, relays, breakers, diodes, transistors, resistors, coils, capacitors, and the like.

The electrical power supply system 26 includes a first electrical power storage device 30 and a second electrical power storage device 32 that serve as auxiliary electrical power sources. The first electrical power storage device 30 and the second electrical power storage device 32 each include a non-illustrated battery. The battery, for example, is a lithium ion battery. In the present embodiment, in the case that the SOC of the first electrical power storage device 30 is mentioned, this term indicates the SOC of the battery of the first electrical power storage device 30. Similarly, in the case that the SOC of the second electrical power storage device 32 is mentioned, this term indicates the SOC of the battery of the second electrical power storage device 32. The first electrical power storage device 30 and the second electrical power storage device 32 may include various sensors such as voltage sensors or the like, and various elements such as fuses, relays, breakers, diodes, transistors, resistors, coils, capacitors, and the like.

The electrical power supply system 26 is equipped with a first load device 34 and a second load device 36. The first load device 34 and the second load device 36 include the VTOL electric motors 20 and the cruise electric motors 24. The first load device 34 and the second load device 36 may include auxiliary equipment such as an oil pump and a cooling water pump.

Each of the first load device 34 and the second load device 36 includes a non-illustrated drive device. The drive device is an inverter having switching elements. By controlling the switching elements, the drive device converts a DC electrical power that is input to the drive device into a three phase AC electrical power, and outputs the AC electrical power to the first load device 34 and the second load device 36.

The first load device 34 and the second load device 36 may include various sensors such as voltage sensors or the like, and various elements such as fuses, relays, breakers, diodes, transistors, resistors, coils, capacitors, and the like.

The electrical power supply system 26 is equipped with an electrical power supply circuit 38. The electrical power supply circuit 38 includes a first electrical power transmission bus 40 and a second electrical power transmission bus 42. The first electrical power transmission bus 40 is capable of supplying, to the first load device 34, the DC electrical power output from the electrical power generating device 28, and the DC electrical power output from the first electrical power storage device 30. The first electrical power storage device 30 is provided in parallel with the electrical power generating device 28. The second electrical power transmission bus 42 is capable of supplying, to the second load device 36, the DC electrical power output from the electrical power generating device 28, and the DC electrical power output from the second electrical power storage device 32. The second electrical power storage device 32 is provided in parallel with the electrical power generating device 28.

The electrical power supply circuit 38 includes a first connection circuit 44, a second connection circuit 46, and a third connection circuit 48. The first connection circuit 44 connects the first electrical power storage device 30 and the first electrical power transmission bus 40. The second connection circuit 46 connects the second electrical power storage device 32 and the second electrical power transmission bus 42. The third connection circuit 48, together with connecting the electrical power generating device 28 to the first electrical power transmission bus 40, also connects the electrical power generating device 28 to the second electrical power transmission bus 42.

The electrical power supply circuit 38 includes a first disconnection device 50. The first disconnection device 50 is capable of disconnecting the electrical power generating device 28 from the first electrical power transmission bus 40. The first disconnection device 50 includes a non-illustrated circuit breaker. The circuit breaker is a contactor. The circuit breaker may also be a relay, a switching element, or the like. The circuit breaker is provided on both of a pair of wires made up from a positive wire and a negative wire of the first electrical power transmission bus 40. The circuit breaker may be provided on only one of the pair of wires of the first electrical power transmission bus 40.

The electrical power supply circuit 38 includes a first reverse flow prevention device 52. The first reverse flow prevention device 52 blocks the supply of electrical power from the first electrical power storage device 30 to the electrical power generating device 28. The first reverse flow prevention device 52 includes a non-illustrated reverse flow prevention element. The reverse flow prevention element, for example, is a diode. The reverse flow prevention element is provided on one of a pair of wires made up from a positive wire and a negative wire of the first electrical power transmission bus 40. The reverse flow prevention element may be provided on both of the pair of wires of the first electrical power transmission bus 40.

The electrical power supply circuit 38 includes a second disconnection device 54. The second disconnection device 54 is capable of disconnecting the electrical power generating device 28 from the second electrical power transmission bus 42. The second disconnection device 54 includes a non-illustrated circuit breaker. The circuit breaker is a contactor. The circuit breaker may also be a relay, a switching element, or the like. The circuit breaker is provided on both of a pair of wires made up from a positive wire and a negative wire of the second electrical power transmission bus 42. The circuit breaker may be provided on only one of the pair of wires of the second electrical power transmission bus 42.

The electrical power supply circuit 38 includes a second reverse flow prevention device 56. The second reverse flow prevention device 56 blocks the supply of electrical power from the second electrical power storage device 32 to the electrical power generating device 28. The second reverse flow prevention device 56 includes a non-illustrated reverse flow prevention element. The reverse flow prevention element, for example, is a diode. The reverse flow prevention element is provided on one of a pair of wires made up from a positive wire and a negative wire of the second electrical power transmission bus 42. The reverse flow prevention element may be provided on both of the pair of wires of the second electrical power transmission bus 42.

The electrical power supply circuit 38 includes a third disconnection device 58. The third disconnection device 58 is capable of disconnecting the first electrical power storage device 30 from the first electrical power transmission bus 40. The third disconnection device 58 includes a non-illustrated circuit breaker. The circuit breaker is a contactor. The circuit breaker may also be a relay, a switching element, or the like. The circuit breaker is provided on both of a pair of wires made up from a positive wire and a negative wire of the first connection circuit 44. The circuit breaker may be provided on only one of the pair of wires of the first connection circuit 44. A pre-charging circuit may be provided in the third disconnection device 58.

The electrical power supply circuit 38 includes a fourth disconnection device 60. The fourth disconnection device 60 is capable of disconnecting the second electrical power storage device 32 from the second electrical power transmission bus 42. The fourth disconnection device 60 includes a non-illustrated circuit breaker. The circuit breaker is a contactor. The circuit breaker may also be a relay, a switching element, or the like. The circuit breaker is provided on both of a pair of wires made up from a positive wire and a negative wire of the second connection circuit 46. The circuit breaker may be provided on only one of the pair of wires of the second connection circuit 46. A pre-charging circuit may be provided in the fourth disconnection device 60.

The electrical power supply circuit 38 includes a first electrical current sensor 62, a second electrical current sensor 64, a third electrical current sensor 66, a fourth electrical current sensor 68, a fifth electrical current sensor 70, a sixth electrical current sensor 72, a seventh electrical current sensor 74, an eighth electrical current sensor 76, and a ninth electrical current sensor 78.

The first electrical current sensor 62 and the second electrical current sensor 64 detect the electrical current flowing through the first connection circuit 44. The third electrical current sensor 66 detects the electrical current flowing through the first electrical power transmission bus 40, at a location closer to the electrical power generating device 28 than is a connected location between the first electrical power transmission bus 40 and the first connection circuit 44. The fourth electrical current sensor 68 detects the electrical current flowing through the first electrical power transmission bus 40, at a location closer to the first load device 34 than is the connected location between the first electrical power transmission bus 40 and the first connection circuit 44.

The fifth electrical current sensor 70 and the sixth electrical current sensor 72 detect the electrical current flowing through the second connection circuit 46. The seventh electrical current sensor 74 detects the electrical current flowing through the second electrical power transmission bus 42, at a location closer to the electrical power generating device 28 than is a connected location between the second electrical power transmission bus 42 and the second connection circuit 46. The eighth electrical current sensor 76 detects the electrical current flowing through the second electrical power transmission bus 42, at a location closer to the second load device 36 than is the connected location between the second electrical power transmission bus 42 and the second connection circuit 46. The ninth electrical current sensor 78 detects the electrical current flowing through the third connection circuit 48.

The electrical power supply system 26 includes a management control device 80, an electrical power generation control device 82, a first electrical power distribution control device 84, a second electrical power distribution control device 86, a first electrical power storage control device 88, and a second electrical power storage control device 90.

The management control device 80 is a control device that serves to manage the electrical power generation control device 82, the first electrical power distribution control device 84, the second electrical power distribution control device 86, the first electrical power storage control device 88, and the second electrical power storage control device 90.

The first electrical power storage control device 88 monitors the first electrical power storage device 30. Further, the first electrical power storage control device 88 controls the third disconnection device 58. The first electrical power storage control device 88 acquires first electrical current information indicating the electrical current detected by the first electrical current sensor 62, and second electrical current information indicating the electrical current detected by the second electrical current sensor 64. The first electrical power storage control device 88 calculates, as a first SOC, the SOC of the first electrical power storage device 30 based on the first electrical current information. The first electrical power storage control device 88 calculates, as a second SOC, the SOC of the first electrical power storage device 30 based on the second electrical current information. A description will be given in detail later concerning the configuration of the first electrical power storage control device 88.

The first electrical power distribution control device 84 controls the first disconnection device 50. The first electrical power distribution control device 84 acquires third electrical current information indicating the electrical current detected by the third electrical current sensor 66, and fourth electrical current information indicating the electrical current detected by the fourth electrical current sensor 68.

The second electrical power storage control device 90 monitors the second electrical power storage device 32. Further, the second electrical power storage control device 90 controls the fourth disconnection device 60. The second electrical power storage control device 90 acquires fifth electrical current information indicating the electrical current detected by the fifth electrical current sensor 70, and sixth electrical current information indicating the electrical current detected by the sixth electrical current sensor 72. The second electrical power storage control device 90 calculates, as a fifth SOC, the SOC of the second electrical power storage device 32 based on the fifth electrical current information. The second electrical power storage control device 90 calculates, as a sixth SOC, the SOC of the second electrical power storage device 32 based on the sixth electrical current information. A description will be given in detail later concerning the configuration of the second electrical power storage control device 90.

The second electrical power distribution control device 86 controls the second disconnection device 54. The second electrical power distribution control device 86 acquires seventh electrical current information indicating the electrical current detected by the seventh electrical current sensor 74, and eighth electrical current information indicating the electrical current detected by the eighth electrical current sensor 76.

The electrical power generation control device 82 controls the electrical power generating device 28. The electrical power generation control device 82, in accordance with the required electrical power, controls the rotational speed and the torque of the gas turbine engine. The required electrical power is the total electrical power required by the first load device 34, the second load device 36, the first electrical power storage device 30, and the second electrical power storage device 32, and is determined by the management control device 80. The electrical power generation control device 82 acquires ninth electrical current information indicating the electrical current detected by the ninth electrical current sensor 78.

### [Configuration of First Electrical Power Storage Control Device]

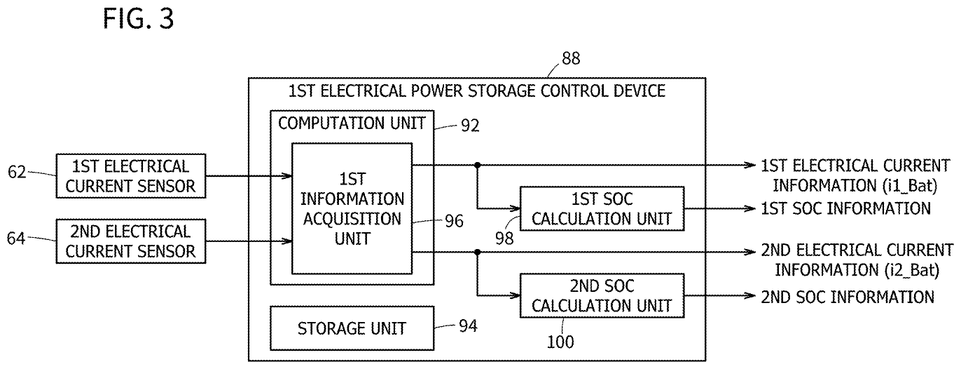

FIG. 3 is a block diagram showing a configuration of the first electrical power storage control device 88 according to the one embodiment.

The first electrical power storage control device 88 includes a computation unit 92 and a storage unit 94. The computation unit 92 is a processor such as a CPU (Central Processing Unit) or a GPU (Graphics Processing Unit) or the like. The computation unit 92 includes a first information acquisition unit 96. The first information acquisition unit 96 is realized by a program that is stored in the storage unit 94 being executed in the computation unit 92. At least a portion of the first information acquisition unit 96 may be realized by an integrated circuit such as an ASIC (Application Specific Integrated Circuit), an FPGA (Field-Programmable Gate Array), or the like. At least a portion of the first information acquisition unit 96 may be realized by an electronic circuit including a discrete device.

The storage unit 94 is a computer-readable non-transitory tangible storage medium. The storage unit 94 is constituted by a non-illustrated volatile memory and a non-illustrated non-volatile memory. The volatile memory, for example, is a RAM (Random Access Memory) or the like. The non-volatile memory, for example, is a ROM (Read Only Memory), a flash memory, or the like. Data and the like are stored, for example, in the volatile memory. A program, a table, a map, and the like are stored, for example, in the non-volatile memory. At least a portion of the storage unit 94 may be provided in the processor, the integrated circuit, or the like described above. At least a portion of the storage unit 94 may be installed in a device that is connected by a network to the moving object 10.

The first information acquisition unit 96 acquires the first electrical current information indicating the electrical current detected by the first electrical current sensor 62, and the second electrical current information indicating the electrical current detected by the second electrical current sensor 64.

The first electrical power storage control device 88 includes a first SOC calculation unit 98 and a second SOC calculation unit 100. Each of the first SOC calculation unit 98 and the second SOC calculation unit 100 can be realized, for example, by processing circuitry. The processing circuitry may be constituted by an integrated circuit such as an ASIC, an FPGA, or the like. Further, the processing circuitry may also be constituted by an electronic circuit including a discrete device. Moreover, the processing circuitry may be constituted by a processor such as a CPU, a GPU, or the like. In this case, the processing circuitry can be realized by a program that is stored in a non-illustrated storage unit being executed by the processor.

The first SOC calculation unit 98 calculates, as a first SOC, the SOC of the first electrical power storage device 30 based on the first electrical current information. The second SOC calculation unit 100 calculates, as a second SOC, the SOC of the first electrical power storage device 30 based on the second electrical current information.

### [Configuration of Second Electrical Power Storage Control Device]

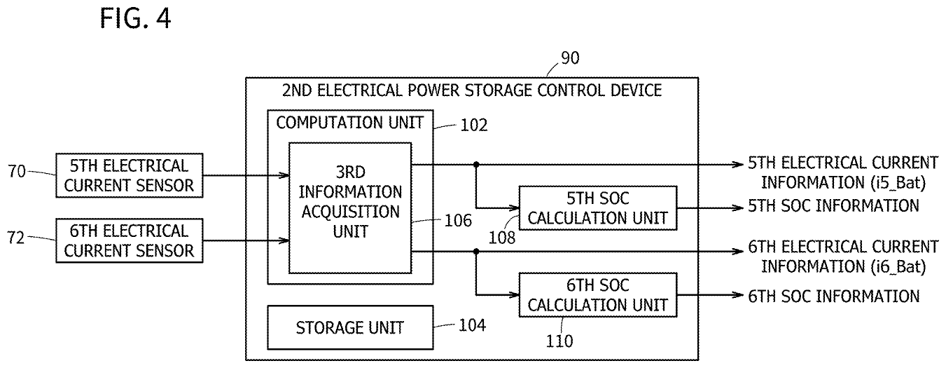

FIG. 4 is a block diagram showing a configuration of the second electrical power storage control device 90 according to the one embodiment.

The second electrical power storage control device 90 includes a computation unit 102 and a storage unit 104. The computation unit 102 is a processor such as a CPU, a GPU, or the like. The computation unit 102 includes a third information acquisition unit 106. The third information acquisition unit 106 is realized by a program that is stored in the storage unit 104 being executed in the computation unit 102. At least a portion of the third information acquisition unit 106 may be realized by an integrated circuit such as an ASIC, an FPGA, or the like. At least a portion of the third information acquisition unit 106 may be realized by an electronic circuit including a discrete device.

The storage unit 104 is a computer-readable non-transitory tangible storage medium. The storage unit 104 is constituted by a non-illustrated volatile memory and a non-illustrated non-volatile memory. The volatile memory, for example, is a RAM or the like. The non-volatile memory, for example, is a ROM, a flash memory, or the like. Data and the like are stored, for example, in the volatile memory. A program, a table, a map, and the like are stored, for example, in the non-volatile memory. At least a portion of the storage unit 104 may be provided in the processor, the integrated circuit, or the like described above. At least a portion of the storage unit 104 may be installed in a device that is connected by a network to the moving object 10.

The second electrical power storage control device 90 acquires the fifth electrical current information indicating the electrical current detected by the fifth electrical current sensor 70, and the sixth electrical current information indicating the electrical current detected by the sixth electrical current sensor 72.

The second electrical power storage control device 90 includes a fifth SOC calculation unit 108 and a sixth SOC calculation unit 110. Each of the fifth SOC calculation unit 108 and the sixth SOC calculation unit 110 can be realized, for example, by processing circuitry. The processing circuitry may be constituted by an integrated circuit such as an ASIC, an FPGA, or the like. Further, the processing circuitry may also be constituted by an electronic circuit including a discrete device. Moreover, the processing circuitry may be constituted by a processor such as a CPU, a GPU, or the like. In this case, the processing circuitry can be realized by a program that is stored in a non-illustrated storage unit being executed by the processor.

The fifth SOC calculation unit 108 calculates, as a fifth SOC, the SOC of the second electrical power storage device 32 based on the fifth electrical current information. The sixth SOC calculation unit 110 calculates, as a sixth SOC, the SOC of the second electrical power storage device 32 based on the sixth electrical current information.

### [Configuration of Management Control Device]

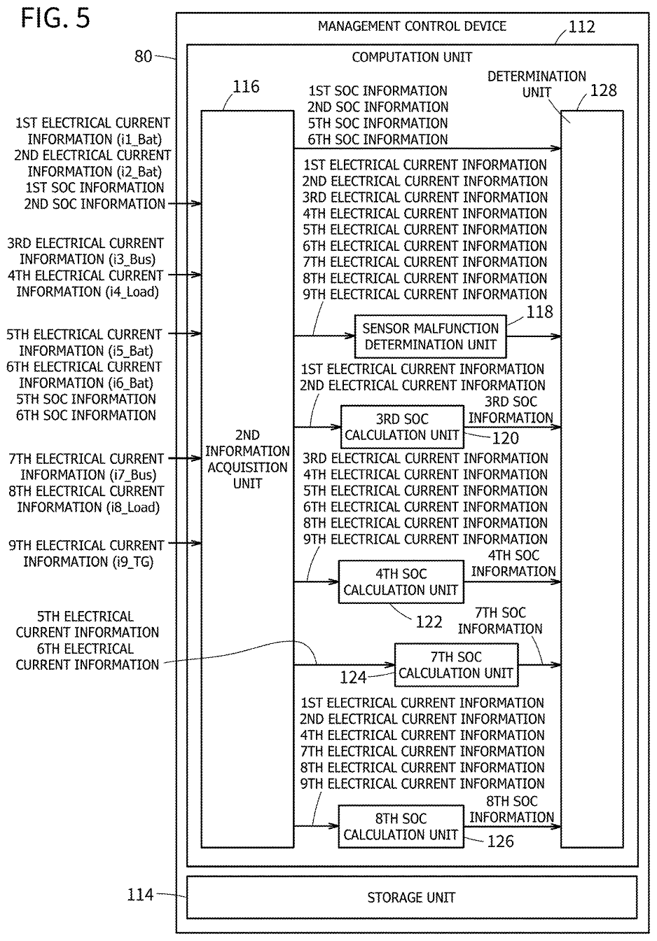

FIG. 5 is a block diagram showing a configuration of the management control device 80 according to the one embodiment.

The management control device 80 includes a computation unit 112 and a storage unit 114. The computation unit 112 is a processor such as a CPU, a GPU, or the like. The computation unit 112 includes a second information acquisition unit 116, a sensor malfunction determination unit 118, a third SOC calculation unit 120, a fourth SOC calculation unit 122, a seventh SOC calculation unit 124, an eighth SOC calculation unit 126, and a determination unit 128. The second information acquisition unit 116, the sensor malfunction determination unit 118, the third SOC calculation unit 120, the fourth SOC calculation unit 122, the seventh SOC calculation unit 124, the eighth SOC calculation unit 126, and the determination unit 128 are realized by a program that is stored in the storage unit 114 being executed in the computation unit 112. At least a portion of the second information acquisition unit 116, the sensor malfunction determination unit 118, the third SOC calculation unit 120, the fourth SOC calculation unit 122, the seventh SOC calculation unit 124, the eighth SOC calculation unit 126, and the determination unit 128 may be realized by an integrated circuit such as an ASIC, an FPGA, or the like. At least a portion of the second information acquisition unit 116, the sensor malfunction determination unit 118, the third SOC calculation unit 120, the fourth SOC calculation unit 122, the seventh SOC calculation unit 124, the eighth SOC calculation unit 126, and the determination unit 128 may be realized by an electronic circuit including a discrete device.

The storage unit 114 is a computer-readable non-transitory tangible storage medium. The storage unit 114 is constituted by a non-illustrated volatile memory and a non-illustrated non-volatile memory. The volatile memory, for example, is a RAM or the like. The non-volatile memory, for example, is a ROM, a flash memory, or the like. Data and the like are stored, for example, in the volatile memory. A program, a table, a map, and the like are stored, for example, in the non-volatile memory. At least a portion of the storage unit 114 may be provided in the processor, the integrated circuit, or the like described above. At least a portion of the storage unit 114 may be installed in a device that is connected by a network to the moving object 10.

The second information acquisition unit 116 acquires, from the first electrical power storage control device 88, the first electrical current information, the second electrical current information, first SOC information, and second SOC information. The second information acquisition unit 116 acquires, from the first electrical power distribution control device 84, the third electrical current information and the fourth electrical current information. The second information acquisition unit 116 acquires, from the second electrical power storage control device 90, the fifth electrical current information, the sixth electrical current information, fifth SOC information, and sixth SOC information. The second information acquisition unit 116 acquires, from the second electrical power distribution control device 86, the seventh electrical current information and the eighth electrical current information. The second information acquisition unit 116 acquires the ninth electrical current information from the electrical power generation control device 82.

The first Soc information is information indicating the first SOC. The second SOC information is information indicating the second SOC. The fifth SOC information is information indicating the fifth SOC. The sixth SOC information is information indicating the sixth SOC.

The sensor malfunction determination unit 118 determines whether or not each of the first electrical current sensor 62, the second electrical current sensor 64, the third electrical current sensor 66, the fourth electrical current sensor 68, the fifth electrical current sensor 70, the sixth electrical current sensor 72, the seventh electrical current sensor 74, the eighth electrical current sensor 76, and the ninth electrical current sensor 78 has malfunctioned. A malfunction of each of the electrical current sensors is determined based on the first electrical current information, the second electrical current information, the third electrical current information, the fourth electrical current information, the fifth electrical current information, the sixth electrical current information, the seventh electrical current information, the eighth electrical current information, and the ninth electrical current information. The method for determining whether each of the electrical current sensors has malfunctioned will be described in detail later.

The third SOC calculation unit 120 calculates, as a third soc, the SOC of the first electrical power storage device 30 based on the first electrical current information or the second electrical current information. The third SOC calculation unit 120 transmits third SOC information indicating the third SOC to the determination unit 128.

The fourth SOC calculation unit 122 calculates, as a fourth SOC, the SOC of the first electrical power storage device 30 based on the third electrical current information and the fourth electrical current information. The fourth SOC calculation unit 122 may also calculate, as the fourth SOC, the SOC of the first electrical power storage device 30 based on the fourth electrical current information, the fifth electrical current information, the eighth electrical current information, and the ninth electrical current information. The fourth SOC calculation unit 122 may also calculate, as the fourth SOC, the SOC of the first electrical power storage device 30 based on the fourth electrical current information, the sixth electrical current information, the eighth electrical current information, and the ninth electrical current information. The fourth SOC calculation unit 122 transmits fourth SOC information indicating the fourth SOC to the determination unit 128.

The seventh SOC calculation unit 124 calculates, as a seventh SOC, the SOC of the second electrical power storage device 32 based on the fifth electrical current information or the sixth electrical current information. The seventh SOC calculation unit 124 transmits seventh SOC information indicating the seventh SOC to the determination unit 128.

The eighth SOC calculation unit 126 calculates, as an eighth Soc, the SOC of the second electrical power storage device 32 based on the seventh electrical current information and the eighth electrical current information. The eighth SOC calculation unit 126 may also calculate, as the eighth Soc, the SOC of the second electrical power storage device 32 based on the first electrical current information, the fourth electrical current information, the eighth electrical current information, and the ninth electrical current information. The eighth SOC calculation unit 126 may also calculate, as the eighth SOC, the SOC of the second electrical power storage device 32 based on the second electrical current information, the fourth electrical current information, the eighth electrical current information, and the ninth electrical current information. The eighth SOC calculation unit 126 transmits eighth SOC information indicating the eighth SOC to the determination unit 128.

The determination unit 128 determines the SOC of the first electrical power storage device 30 and the SOC of the second electrical power storage device 32. The method for determining the SOC of the first electrical power storage device 30 and the SOC of the second electrical power storage device 32 will be described in detail later.

### [Method for Determining Malfunction of Electrical Current Sensor]

The sensor malfunction determination unit 118 determines a malfunction of each of the electrical current sensors based on the first electrical current information, the second electrical current information, the third electrical current information, the fourth electrical current information, the fifth electrical current information, the sixth electrical current information, the seventh electrical current information, the eighth electrical current information, and the ninth electrical current information.

In the following description, i1_Bat indicates the electrical current detected by the first electrical current sensor 62, i2_Bat indicates the electrical current detected by the second electrical current sensor 64, i3_Bus indicates the electrical current detected by the third electrical current sensor 66, i4_Load indicates the electrical current detected by the fourth electrical current sensor 68, i5_Bat indicates the electrical current detected by the fifth electrical current sensor 70, i6_Bat indicates the electrical current detected by the sixth electrical current sensor 72, i7_Bus indicates the electrical current detected by the seventh electrical current sensor 74, i8_Load indicates the electrical current detected by the eighth electrical current sensor 76, and i9_TG indicates the electrical current detected by the ninth electrical current sensor 78.

Each of the electrical current sensors detects an electrical current flowing in the direction of the arrow shown in FIG. 2 as a positive value, and detects an electrical current flowing in the direction opposite to the arrow shown in FIG. 2 as a negative value.

(In the Case that all of the Electrical Current Sensors are Normal)

In the case that the electrical currents detected by the electrical current sensors satisfy the following Equation (1) to Equation (5), the sensor malfunction determination unit 118 determines that all of the electrical current sensors are normal.

$$i9\_TG = i3\_Bus + i7\_Bus \qquad ( 1 )$$

$$i4\_Load = i3\_Bus + i1\_Bat \qquad ( 2 )$$

$$i4\_Load = i3\_Bus + i2\_Bat \qquad ( 3 )$$

$$i8\_Load = i7\_Bus + i5\_Bat \qquad ( 4 )$$

$$i8\_Load = i7\_Bus + i6\_Bat \qquad ( 5 )$$

(In the Case that the First Electrical Current Sensor has Malfunctioned)

In the case that the electrical currents detected by the electrical current sensors satisfy the following Equation (6) to Equation (10), the sensor malfunction determination unit 118 determines that the first electrical current sensor 62 has malfunctioned.

$$i9\_TG = i3\_Bus + i7\_Bus \qquad ( 6 )$$

$$i4\_Load \neq i3\_Bus + i1\_Bat \qquad ( 7 )$$

$$i4\_Load = i3\_Bus + i2\_Bat \qquad ( 8 )$$

$$i8\_Load = i7\_Bus + i5\_Bat \qquad ( 9 )$$

$$i8\_Load = i7\_Bus + i6\_Bat \qquad ( 10 )$$

(In the Case that the Second Electrical Current Sensor has Malfunctioned)

In the case that the electrical currents detected by the electrical current sensors satisfy the following Equation (11) to Equation (15), the sensor malfunction determination unit 118 determines that the second electrical current sensor 64 has malfunctioned.

$$i9\_TG = i3\_Bus + i7\_Bus \qquad ( 11 )$$

$$i4\_Load = i3\_Bus + i1\_Bat \qquad ( 12 )$$

$$i4\_Load \neq i3\_Bus + i2\_Bat \qquad ( 13 )$$

$$i8\_Load = i7\_Bus + i5\_Bat \qquad ( 14 )$$

$$i8\_Load = i7\_Bus + i6\_Bat \qquad ( 15 )$$

(In the Case that the Third Electrical Current Sensor has Malfunctioned)

In the case that the electrical currents detected by the electrical current sensors satisfy the following Equation (16) to Equation (20), the sensor malfunction determination unit 118 determines that the third electrical current sensor 66 has malfunctioned.

$$i9\_TG \neq i3\_Bus + i7\_Bus \qquad ( 16 )$$

$$i4\_Load \neq i3\_Bus + i1\_Bat \qquad ( 17 )$$

$$i4\_Load \neq i3\_Bus + i2\_Bat \qquad ( 18 )$$

$$i8\_Load = i7\_Bus + i5\_Bat \qquad ( 19 )$$

$$i8\_Load = i7\_Bus + i6\_Bat \qquad ( 20 )$$

(In the Case that the Fourth Electrical Current Sensor has Malfunctioned)

In the case that the electrical currents detected by the electrical current sensors satisfy the following Equation (21) to Equation (25), the sensor malfunction determination unit 118 determines that the fourth electrical current sensor 68 has malfunctioned.

$$i9\_TG = i3\_Bus + i7\_Bus \qquad ( 21 )$$

$$i4\_Load \neq i3\_Bus + i1\_Bat \qquad ( 22 )$$

$$i4\_Load \neq i3\_Bus + i2\_Bat \qquad ( 23 )$$

$$i8\_Load = i7\_Bus + i5\_Bat \qquad ( 24 )$$

$$i8\_Load = i7\_Bus + i6\_Bat \qquad ( 25 )$$

(In the Case that the Fifth Electrical Current Sensor has Malfunctioned)

In the case that the electrical currents detected by the electrical current sensors satisfy the following Equation (26) to Equation (30), the sensor malfunction determination unit 118 determines that the fifth electrical current sensor 70 has malfunctioned.

$$i9\_TG = i3\_Bus + i7\_Bus \qquad ( 26 )$$

$$i4\_Load = i3\_Bus + i1\_Bat \qquad ( 27 )$$

$$i4\_Load = i3\_Bus + i2\_Bat \qquad ( 28 )$$

$$i8\_Load \neq i7\_Bus + i5\_Bat \qquad ( 29 )$$

$$i8\_Load = i7\_Bus + i6\_Bat \qquad ( 30 )$$

(In the Case that the Sixth Electrical Current Sensor has Malfunctioned)

In the case that the electrical currents detected by the electrical current sensors satisfy the following Equation (31) to Equation (35), the sensor malfunction determination unit 118 determines that the sixth electrical current sensor 72 has malfunctioned.

$$i9\_TG = i3\_Bus + i7\_Bus \qquad ( 31 )$$

$$i4\_Load = i3\_Bus + i1\_Bat \qquad ( 32 )$$

$$i4\_Load = i3\_Bus + i2\_Bat \qquad ( 33 )$$

$$i8\_Load = i7\_Bus + i5\_Bat \qquad ( 34 )$$

$$i8\_Load \neq i7\_Bus + i6\_Bat \qquad ( 35 )$$

(In the Case that the Seventh Electrical Current Sensor has Malfunctioned)

In the case that the electrical currents detected by the electrical current sensors satisfy the following Equation (36) to Equation (40), the sensor malfunction determination unit 118 determines that the seventh electrical current sensor 74 has malfunctioned.

$$i9\_TG \neq i3\_Bus + i7\_Bus \qquad ( 36 )$$

$$i4\_Load = i3\_Bus + i1\_Bat \qquad ( 37 )$$

$$i4\_Load = i3\_Bus + i2\_Bat \qquad ( 38 )$$

$$i8\_Load \neq i7\_Bus + i5\_Bat \qquad ( 39 )$$

$$i8\_Load \neq i7\_Bus + i6\_Bat \qquad ( 40 )$$

(In the Case that the Eighth Electrical Current Sensor has Malfunctioned)

In the case that the electrical currents detected by the electrical current sensors satisfy the following Equation (41) to Equation (45), the sensor malfunction determination unit 118 determines that the eighth electrical current sensor 76 has malfunctioned.

$$i9\_TG = i3\_Bus + i7\_Bus \qquad ( 41 )$$

$$i4\_Load = i3\_Bus + i1\_Bat \qquad ( 42 )$$

$$i4\_Load = i3\_Bus + i2\_Bat \qquad ( 43 )$$

$$i8\_Load \neq i7\_Bus + i5\_Bat \qquad ( 44 )$$

$$i8\_Load \neq i7\_Bus + i6\_Bat \qquad ( 45 )$$

(In the Case that the Ninth Electrical Current Sensor has Malfunctioned)

In the case that the electrical currents detected by the electrical current sensors satisfy the following Equation (46) to Equation (50), the sensor malfunction determination unit 118 determines that the ninth electrical current sensor 78 has malfunctioned.

$$i9\_TG \neq i3\_Bus + i7\_Bus \qquad ( 46 )$$

$$i4\_Load = i3\_Bus + i1\_Bat \qquad ( 47 )$$

$$i4\_Load = i3\_Bus + i2\_Bat \qquad ( 48 )$$

$$i8\_Load = i7\_Bus + i5\_Bat \qquad ( 49 )$$

$$i8\_Load = i7\_Bus + i6\_Bat \qquad ( 50 )$$

### [Method of Calculating SOC]

The first SOC calculation unit 98 calculates the first Soc using the following Equation (51). In Equation (51), SOC_1(t) indicates the first SOC at time t. SOC1(t0) indicates the SOC of the first electrical power storage device 30 at time to. The SOC of the first electrical power storage device 30 at time to is the SOC of the first electrical power storage device 30 that is determined by the determination unit 128 in a previous control cycle. FCC is the fully charged capacity of the battery of the first electrical power storage device 30, and is generally expressed in units of [Ah].

$$SOC\_ 1 ( t ) = \frac{{\int }_{t 0}^{t} i1\_Bat dt}{FCC \cdot 3600} + SOC 1 ( t 0 ) \qquad ( 51 )$$

The second SOC, the third SOC, the fifth SOC, and the sixth SOC can be determined by a method similar to the method of calculating the first SOC.

The fourth SOC calculation unit 122 calculates, as the fourth SOC, the SOC of the first electrical power storage device 30 based on the third electrical current information and the fourth electrical current information. The fourth SOC calculation unit 122, using the third electrical current information and the fourth electrical current information, estimates the electrical current flowing through the first connection circuit 44. The electrical current flowing through the first connection circuit 44 is determined by the following Equation (52). In equation (52), i_Bat1\hat{ } represents the estimated value of the electrical current flowing through the first connection circuit 44.

$$i\_Bat1 \hat{} = i4\_Load + i8\_load - i9\_TG - i5\_Bat \qquad ( 52 )$$

In Equation (52), instead of the electrical current i5_Bat detected by the fifth electrical current sensor 70, the electrical current i6_Bat detected by the sixth electrical current sensor 72 may be used.

The electrical current flowing through the first connection circuit 44 may be determined by the following Equation (53).

$$i\_Bat1 \hat{} = i4\_Load - i3\_Bus \qquad ( 53 )$$

The fourth SOC calculation unit 122 calculates the fourth SOC using the following Equation (54). In Equation (54), SOC_4(t) indicates the fourth SOC at time t. SOC1(t0) indicates the SOC of the first electrical power storage device 30 at time to. The SOC of the first electrical power storage device 30 at time to is the SOC of the first electrical power storage device 30 that is determined by the determination unit 128 in a previous control cycle.

$$SOC\_ 4 ( t ) = \frac{{\int }_{t 0}^{t} i\_Bat 1 \hat{} dt}{FCC \cdot 3600} + SOC 1 ( t 0 ) \qquad ( 54 )$$

The eighth SOC can be determined by a method similar to the method of calculating the fourth SOC.

### [SOC Management Control]

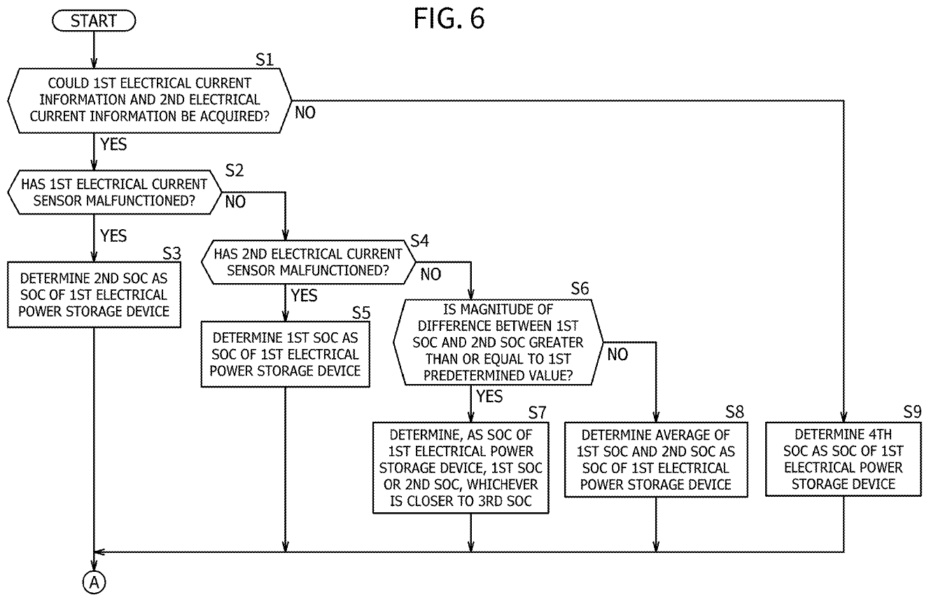

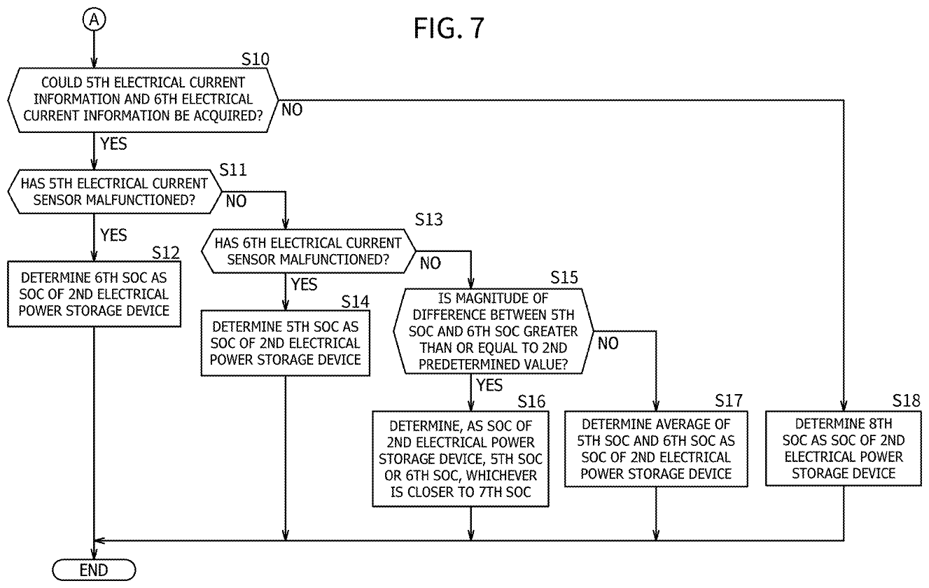

FIG. 6 and FIG. 7 are flowcharts of the SOC management control according to the one embodiment. The SOC management control is repeatedly executed at a predetermined cycle.

In step S1, the second information acquisition unit 116 determines whether or not the first electrical current information and the second electrical current information could be acquired. In the case it is determined that the first electrical current information and the second electrical current information could be acquired (step S1: YES), the process transitions to step S2. In the case it is determined that the first electrical current information and the second electrical current information could not be acquired (step S1: NO), the process transitions to step S9.

In step S2, the sensor malfunction determination unit 118 determines whether or not the first electrical current sensor 62 has malfunctioned. In the case it is determined that the first electrical current sensor 62 has malfunctioned (step S2: YES), the process transitions to step S3. In the case it is determined that the first electrical current sensor 62 has not malfunctioned (step S2: NO), the process transitions to step S4.

In step S3, the determination unit 128 determines the second SOC as the SOC of the first electrical power storage device 30. Thereafter, the process transitions to step S10.

In step S4, the sensor malfunction determination unit 118 determines whether or not the second electrical current sensor 64 has malfunctioned. In the case it is determined that the second electrical current sensor 64 has malfunctioned (step S4: YES), the process transitions to step S5. In the case it is determined that the second electrical current sensor 64 has not malfunctioned (step S4: NO), the process transitions to step S6.

In step S5, the determination unit 128 determines the first SOC as the SOC of the first electrical power storage device 30. Thereafter, the process transitions to step S10.

In step S6, the sensor malfunction determination unit 118 determines whether or not the magnitude of the difference between the first Soc and the second SOC is greater than or equal to a first predetermined value. The magnitude of the difference between the first Soc and the second SOC being greater than or equal to the first predetermined value can also be expressed as the absolute value of the difference between the first SOC and the second SOC being greater than or equal to the first predetermined value. In the case that the magnitude of the difference between the first Soc and the second SOC is greater than or equal to the first predetermined value, it is considered that the function of calculating the first SOC in the first SOC calculation unit 98, or alternatively, the function of calculating the second SOC in the second SOC calculation unit 100 has been lost. In the case it is determined that the magnitude of the difference between the first SOC and the second SOC is greater than or equal to the first predetermined value (step S6: YES), the process transitions to step S7. In the case it is determined that the magnitude of the difference between the first soc and the second SOC is less than the first predetermined value (step S6: NO), the process transitions to step S8.

In step S7, the determination unit 128 determines, as the SOC of the first electrical power storage device 30, the first SOC or the second SOC, whichever is closer to the third SOC. Thereafter, the process transitions to step S10.

In step S8, the determination unit 128 determines, as the SOC of the first electrical power storage device 30, the average value of the first SOC and the second SOC. Thereafter, the process transitions to step S10.

In step S1, in the case it is determined that the first electrical current information and the second electrical current information could not be acquired, it is considered that a state has occurred in which the communication between the management control device 80 and the first electrical power storage control device 88 is not possible. In that case, in step S9, the determination unit 128 determines the fourth SOC as the SOC of the first electrical power storage device 30. Thereafter, the process transitions to step S10.

In step S10, the second information acquisition unit 116 determines whether or not the fifth electrical current information and the sixth electrical current information could be acquired. In the case it is determined that the fifth electrical current information and the sixth electrical current information could be acquired (step S10: YES), the process transitions to step S11. In the case it is determined that the fifth electrical current information and the sixth electrical current information could not be acquired (step S10: NO), the process transitions to step S18.

In step S11, the sensor malfunction determination unit 118 determines whether or not the fifth electrical current sensor 70 has malfunctioned. In the case it is determined that the fifth electrical current sensor 70 has malfunctioned (step S11: YES), the process transitions to step S12. In the case it is determined that the fifth electrical current sensor 70 has not malfunctioned (step S11: NO), the process transitions to step S13.

In step S12, the determination unit 128 determines the sixth SOC as the SOC of the second electrical power storage device 32. Thereafter, the SOC management control comes to an end.

In step S13, the sensor malfunction determination unit 118 determines whether or not the sixth electrical current sensor 72 has malfunctioned. In the case it is determined that the sixth electrical current sensor 72 has malfunctioned (step S13: YES), the process transitions to step S14. In the case it is determined that the sixth electrical current sensor 72 has not malfunctioned (step S13: NO), the process transitions to step S15.

In step S14, the determination unit 128 determines the fifth SOC as the SOC of the second electrical power storage device 32. Thereafter, the SOC management control comes to an end.

In step S15, the sensor malfunction determination unit 118 determines whether or not the magnitude of the difference between the fifth SOC and the sixth SOC is greater than or equal to a second predetermined value. The second predetermined value may be the same as the first predetermined value, or may be different from the first predetermined value. The magnitude of the difference between the fifth SOC and the sixth SOC being greater than or equal to the second predetermined value can also be expressed as the absolute value of the difference between the fifth SOC and the sixth SOC being greater than or equal to the second predetermined value. In the case that the magnitude of the difference between the fifth SOC and the sixth SOC is greater than or equal to the second predetermined value, it is considered that the function of calculating the fifth Soc in the fifth SOC calculation unit 108, or alternatively, the function of calculating the sixth Soc in the sixth SOC calculation unit 110 has been lost. In the case it is determined that the magnitude of the difference between the fifth SOC and the sixth SOC is greater than or equal to the second predetermined value (step S15: YES), the process transitions to step S16. In the case it is determined that the magnitude of the difference between the fifth SOC and the sixth Soc is less than the second predetermined value (step S15: NO), the process transitions to step S17.

In step S16, the determination unit 128 determines, as the SOC of the second electrical power storage device 32, the fifth SOC or the sixth SOC, whichever is closer to the seventh SOC. Thereafter, the SOC management control comes to an end.

In step S17, the determination unit 128 determines, as the SOC of the second electrical power storage device 32, the average value of the fifth SOC and the sixth SOC. Thereafter, the SOC management control comes to an end.

In step S10, in the case it is determined that the fifth electrical current information and the sixth electrical current information could not be acquired, it is considered that a state has occurred in which the communication between the management control device 80 and the second electrical power storage control device 90 is not possible. In that case, in step S18, the determination unit 128 determines the eighth SOC as the SOC of the second electrical power storage device 32. Thereafter, the SOC management control comes to an end.

### [Operations and Effects]

According to the present embodiment, two electrical current sensors (the first electrical current sensor 62 and the second electrical current sensor 64) that serve to detect the electrical current flowing through the first connection circuit 44 are provided. Solely based on the electrical currents that are detected by the two electrical current sensors, it is not possible to determine which of the electrical current sensors has malfunctioned. However, according to the present embodiment, by using the electrical current detected by the third electrical current sensor 66 and the fourth electrical current sensor 68 that serves to detect the electrical current at other locations, it is possible to determine which of the first electrical current sensor 62 and the second electrical current sensor 64 has malfunctioned.

According to the present embodiment, the first SOC calculation unit 98 and the second SOC calculation unit 100 that serve to calculate the SOC of the first electrical power storage device 30 are provided in the first electrical power storage control device 88. Further, the third SOC calculation unit 120 that serves to calculate the SOC of the first electrical power storage device 30 is provided in the management control device 80. The management control device 80, by comparing the third SOC calculated by the third SOC calculation unit 120, the first SOC calculated by the first SOC calculation unit 98, and the second SOC calculated by the second SOC calculation unit 100, is capable of determining which of the first SOC and the second SOC more accurately indicates the SOC of the first electrical power storage device 30.

According to the present embodiment, the fourth SOC calculation unit 122 is provided in the management control device 80. The fourth SOC calculation unit 122 estimates the electrical current flowing through the first connection circuit 44, without using the first electrical current information and the second electrical current information, and using the fourth electrical current information, the fifth electrical current information, the eighth electrical current information, and the ninth electrical current information. Alternatively, the fourth SOC calculation unit 122 estimates the electrical current flowing through the first connection circuit 44, without using the first electrical current information and the second electrical current information, and using the fourth electrical current information, the sixth electrical current information, the eighth electrical current information, and the ninth electrical current information. Alternatively, the fourth SOC calculation unit 122 estimates the electrical current flowing through the first connection circuit 44, without using the first electrical current information and the second electrical current information, and using the third electrical current information and the fourth electrical current information. The fourth SOC calculation unit 122, using the estimated electrical current flowing through the first connection circuit 44, is capable of calculating the SOC of the first electrical power storage device 30. In accordance with this feature, even in the case that communication cannot be carried out between the management control device 80 and the first electrical power storage control device 88, the SOC of the first electrical power storage device 30 can be calculated in the management control device 80.

In relation to the above-described embodiment, the following supplementary notes are further disclosed.

### Supplementary Note 1

The electrical power supply system (26) according to the present disclosure comprises the first electrical power transmission bus (40) that supplies, to the first load device (34), the direct current electrical power output from the electrical power generating device (28) and the direct current electrical power output from the first electrical power storage device (30) that is disposed in parallel with the electrical power generating device, the first electrical current sensor (62) and the second electrical current sensor (64) that detect the electrical current flowing through the first connection circuit (44) that connects the first electrical power storage device and the first electrical power transmission bus, the third electrical current sensor (66) that detects the electrical current flowing through the first electrical power transmission bus, at a location closer to the electrical power generating device than is the connected location between the first electrical power transmission bus and the first connection circuit, the fourth electrical current sensor (68) that detects the electrical current flowing through the first electrical power transmission bus, at a location closer to the first load device than is the connected location between the first electrical power transmission bus and the first connection circuit, the first electrical power storage control device (88) including the first information acquisition unit (96) that acquires the first electrical current information indicating the electrical current detected by the first electrical current sensor, and acquires the second electrical current information indicating the electrical current detected by the second electrical current sensor, and the management control device (80) that manages the first electrical power storage control device, wherein the management control device includes the second information acquisition unit (116) that acquires the first electrical current information and the second electrical current information from the first electrical power storage control device, and acquires the third electrical current information indicating the electrical current detected by the third electrical current sensor, and the fourth electrical current information indicating the electrical current detected by the fourth electrical current sensor, and the sensor malfunction determination unit (118) that determines whether or not the first electrical current sensor has malfunctioned based on the comparison between the first electrical current information, the second electrical current information, the third electrical current information, and the fourth electrical current information. In accordance with such a configuration, it is possible to determine that the first electrical current sensor has malfunctioned.

### Supplementary Note 2

In the electrical power supply system according to Supplementary Note 1, the first electrical power storage control device may further include the first SOC calculation unit (98) that calculates, as the first SOC (State Of Charge), the SOC of the first electrical power storage device based on the electrical current detected by the first electrical current sensor, and the second SOC calculation unit (100) that calculates, as the second SOC, the SOC of the first electrical power storage device based on the electrical current detected by the second electrical current sensor, the second information acquisition unit may further acquire, from the first electrical power storage control device, the first SOC information indicating the first soc, and the second SOC information indicating the second SOC, and the management control device may further include the determination unit that, in the case it is determined by the sensor malfunction determination unit that the first electrical current sensor has malfunctioned, determines the second SOC as the SOC of the first electrical power storage device. In accordance with this feature, even in the case that the first electrical current sensor has malfunctioned, it is possible to determine the SOC of the first electrical power storage device.

### Supplementary Note 3

In the electrical power supply system according to Supplementary Note 2, the management control device may further include the third SOC calculation unit (120) that calculates, as the third SOC, the SOC of the first electrical power storage device, based on the first electrical current information or the second electrical current information, and in the case it is determined by the sensor malfunction determination unit that the first electrical current sensor and the second electrical current sensor are normal, and that the difference between the first SOC and the second SOC is greater than or equal to the first predetermined value, the determination unit may determine, as the SOC of the first electrical power storage device, one of the first SOC or the second SOC that is closer to the third SOC. In accordance with this feature, even in the case that the function of calculating the SOC of the first electrical power storage device is lost in the first SOC calculation unit or the second SOC calculation unit, it is still possible to determine the SOC of the first electrical power storage device.

### Supplementary Note 4

In the electrical power supply system according to Supplementary Note 2, in the case it is determined by the sensor malfunction determination unit that the first electrical current sensor and the second electrical current sensor are normal, and that the difference between the first Soc and the second SOC is less than the first predetermined value, the determination unit may determine the SOC of the first electrical power storage device based on the first Soc and the second SOC.

### Supplementary Note 5

In the electrical power supply system according to Supplementary Note 2, the management control device may further include the fourth SOC calculation unit (122) that calculates, as the fourth Soc, the SOC of the first electrical power storage device, based on the third electrical current information and the fourth electrical current information, and in the case it is determined that the second information acquisition unit is incapable of acquiring the first electrical current information and the second electrical current information from the first electrical power storage control device, the determination unit may determine the fourth SOC as the SOC of the first electrical power storage device. In accordance with this feature, even in the case that communication between the management control device and the first electrical power storage control device is not possible, the SOC of the first electrical power storage device can be determined.

### Supplementary Note 6

In the electrical power supply system according to Supplementary Note 2, there may further be provided the second electrical power transmission bus (42) that supplies, to the second load device (36), the direct current electrical power output from the electrical power generating device, and the direct current electrical power output from the second electrical power storage device (32) that is disposed in parallel with the electrical power generating device, the fifth electrical current sensor (70) and the sixth electrical current sensor (72) that detect the electrical current flowing through the second connection circuit (46) that connects the second electrical power storage device and the second electrical power transmission bus, the seventh electrical current sensor (74) that detects the electrical current flowing through the second electrical power transmission bus, at a location closer to the electrical power generating device than is the connected location between the second electrical power transmission bus and the second connection circuit, the eighth electrical current sensor (76) that detects the electrical current flowing through the second electrical power transmission bus, at a location closer to the second load device than is the connected location between the second electrical power transmission bus and the second connection circuit, and the second electrical power storage control device (90) including the third information acquisition unit (106) that acquires the fifth electrical current information indicating the electrical current detected by the fifth electrical current sensor, and acquires the sixth electrical current information indicating the electrical current detected by the sixth electrical current sensor, wherein the management control device may further manage the second electrical power storage control device, the second information acquisition unit may further acquire the fifth electrical current information and the sixth electrical current information from the second electrical power storage control device, and may further acquire the seventh electrical current information indicating the electrical current detected by the seventh electrical current sensor and the eighth electrical current information indicating the electrical current detected by the eighth electrical current sensor, and the sensor malfunction determination unit may further determine whether or not the fifth electrical current sensor has malfunctioned, based on a comparison between the fifth electrical current information, the sixth electrical current information, the seventh electrical current information, and the eighth electrical current information.

### Supplementary Note 7

In the electrical power supply system according to Supplementary Note 6, there may further be provided the ninth electrical current sensor (78) that detects the electrical current flowing through the third connection circuit (48) that connects the electrical power generating device, and the first electrical power transmission bus and the second electrical power transmission bus, wherein the second information acquisition unit may further acquire the ninth electrical current information indicating the electrical current detected by the ninth electrical current sensor, the management control device may further include the fourth SOC calculation unit that calculates, as the fourth SOC, the SOC of the first electrical power storage device, based on the fourth electrical current information, the fifth electrical current information, the eighth electrical current information, and the ninth electrical current information, and in the case that the second information acquisition unit is incapable of acquiring the first electrical current information and the second electrical current information from the first electrical power storage control device, the determination unit may determine the fourth SOC as the SOC of the first electrical power storage device.

### Supplementary Note 8

The moving object (10) according to the present disclosure is equipped with the electrical power supply system according to any one of Supplementary Notes 1 to 7.

Although concerning the present disclosure, a detailed description thereof has been presented above, the present disclosure is not necessarily limited to the individual embodiments described above. These embodiments may be subjected to various additions, substitutions, modifications, partial deletions and the like, within a range that does not deviate from the essence and gist of the present disclosure, or the spirit of the present disclosure as derived from the contents described in the claims and equivalents thereof. Further, the embodiments can also be implemented together in combination. For example, in the above-described embodiments, the order of the operations and the order of the processes are illustrated as examples, and the present disclosure is not necessarily limited to these features. The same also applies to cases in which numerical values or mathematical expressions are used in the description of the aforementioned embodiments.

1. An electrical power supply system, comprising:
a first electrical power transmission bus configured to supply, to a first load device, a direct current electrical power output from an electrical power generating device and a direct current electrical power output from a first electrical power storage device configured to be disposed in parallel with the electrical power generating device;
a first electrical current sensor and a second electrical current sensor each configured to detect an electrical current flowing through a first connection circuit configured to connect the first electrical power storage device and the first electrical power transmission bus;
a third electrical current sensor configured to detect an electrical current flowing through the first electrical power transmission bus, at a location closer to the electrical power generating device than is a connected location between the first electrical power transmission bus and the first connection circuit;
a fourth electrical current sensor configured to detect an electrical current flowing through the first electrical power transmission bus, at a location closer to the first load device than is the connected location between the first electrical power transmission bus and the first connection circuit;
a first electrical power storage control device including one or more processors that execute computer-executable instructions stored in a memory; and
a management control device including one or more processors that execute computer-executable instructions stored in a memory, and configured to manage the first electrical power storage control device,
wherein the one or more processors execute the computer-executable instructions to cause the first electrical power storage control device to acquire first electrical current information indicating the electrical current detected by the first electrical current sensor, and second electrical current information indicating the electrical current detected by the second electrical current sensor, and
the one or more processors execute the computer-executable instructions to cause the management control device to:
acquire the first electrical current information and the second electrical current information from the first electrical power storage control device, and acquire third electrical current information indicating the electrical current detected by the third electrical current sensor, and fourth electrical current information indicating the electrical current detected by the fourth electrical current sensor; and
determine whether or not the first electrical current sensor has malfunctioned based on a comparison between the first electrical current information, the second electrical current information, the third electrical current information, and the fourth electrical current information.

2. The electrical power supply system according to claim 1, wherein
the one or more processors execute the computer-executable instructions to cause the first electrical power storage control device to:
calculate, as a first state of charge, a state of charge of the first electrical power storage device based on the electrical current detected by the first electrical current sensor; and
calculate, as a second state of charge, the state of charge of the first electrical power storage device based on the electrical current detected by the second electrical current sensor, and
the one or more processors execute the computer-executable instructions to cause the management control device to:
acquire, from the first electrical power storage control device, first state of charge information indicating the first state of charge, and second state of charge information indicating the second state of charge; and
in a case that it is determined that the first electrical current sensor has malfunctioned, determine the second state of charge as the state of charge of the first electrical power storage device.

3. The electrical power supply system according to claim 2, wherein the one or more processors execute the computer-executable instructions to cause the management control device to:
calculate, as a third state of charge, the state of charge of the first electrical power storage device, based on the first electrical current information or the second electrical current information; and
determine, as the state of charge of the first electrical power storage device, one of the first state of charge or the second state of charge that is closer to the third state of charge, in a case that it is determined that the first electrical current sensor and the second electrical current sensor are normal, and that a difference between the first state of charge and the second state of charge is greater than or equal to a first predetermined value.

4. The electrical power supply system according to claim 2, wherein the one or more processors execute the computer-executable instructions to cause the management control device to determine the state of charge of the first electrical power storage device based on the first state of charge and the second state of charge, in a case that it is determined that the first electrical current sensor and the second electrical current sensor are normal, and that a difference between the first state of charge and the second state of charge is less than a first predetermined value.

5. The electrical power supply system according to claim 2, wherein the one or more processors execute the computer-executable instructions to cause the management control device to:
calculate, as a fourth state of charge, the state of charge of the first electrical power storage device, based on the third electrical current information and the fourth electrical current information; and
determine the fourth state of charge as the state of charge of the first electrical power storage device, in a case that the first electrical current information and the second electrical current information are not acquirable from the first electrical power storage control device.

6. The electrical power supply system according to claim 2, further comprising:
a second electrical power transmission bus configured to supply, to a second load device, the direct current electrical power output from the electrical power generating device, and a direct current electrical power output from a second electrical power storage device configured to be disposed in parallel with the electrical power generating device;
a fifth electrical current sensor and a sixth electrical current sensor each configured to detect an electrical current flowing through a second connection circuit configured to connect the second electrical power storage device and the second electrical power transmission bus;
a seventh electrical current sensor configured to detect an electrical current flowing through the second electrical power transmission bus, at a location closer to the electrical power generating device than is a connected location between the second electrical power transmission bus and the second connection circuit;
an eighth electrical current sensor configured to detect an electrical current flowing through the second electrical power transmission bus, at a location closer to the second load device than is the connected location between the second electrical power transmission bus and the second connection circuit; and
a second electrical power storage control device including one or more processors that execute computer-executable instructions stored in a memory,
wherein the one or more processors execute the computer-executable instructions to cause the second electrical power storage control device to acquire fifth electrical current information indicating the electrical current detected by the fifth electrical current sensor, and sixth electrical current information indicating the electrical current detected by the sixth electrical current sensor,
the management control device is configured to manage the second electrical power storage control device, and
the one or more processors execute the computer-executable instructions to cause the management control device to:
acquire the fifth electrical current information and the sixth electrical current information from the second electrical power storage control device, and acquire seventh electrical current information indicating the electrical current detected by the seventh electrical current sensor, and eighth electrical current information indicating the electrical current detected by the eighth electrical current sensor; and
determine whether or not the fifth electrical current sensor has malfunctioned based on a comparison between the fifth electrical current information, the sixth electrical current information, the seventh electrical current information, and the eighth electrical current information.

7. The electrical power supply system according to claim 6, further comprising:
a ninth electrical current sensor configured to detect an electrical current flowing through a third connection circuit configured to connect the electrical power generating device, and the first electrical power transmission bus and the second electrical power transmission bus,
wherein the one or more processors execute the computer-executable instructions to cause the management control device to:
acquire ninth electrical current information indicating the electrical current detected by the ninth electrical current sensor;
calculate, as a fourth state of charge, the state of charge of the first electrical power storage device, based on the fourth electrical current information, the fifth electrical current information, the eighth electrical current information, and the ninth electrical current information; and
determine the fourth state of charge as the state of charge of the first electrical power storage device, in a case that the first electrical current information and the second electrical current information are not acquirable from the first electrical power storage control device.

8. A moving object comprising the electrical power supply system according to claim 1.
